(19) United States
(12) Patent Application Publication
(10) Pub. No.: US 2012/0212906 A1
(43) Pub. Date: Aug. 23, 2012

(54) AIR DUCT AND ELECTRONIC DEVICE HAVING THE SAME

(75) Inventor: CHIN-MING CHANG, Tu-Cheng (TW)

(73) Assignee: HON HAI PRECISION INDUSTRY CO., LTD., Tu-Cheng (TW)

(21) Appl. No.: 13/193,614

(22) Filed: Jul. 29, 2011

(30) Foreign Application Priority Data
Feb. 18, 2011 (TW) 100105482

(51) Int. Cl. H05K 7/20; F16L 9/00

(52) U.S. Cl. 361/695; 138/177

(57) ABSTRACT

An electronic device includes a motherboard having first and second electronic components, and an air duct. The air duct includes a cover portion and a guiding panel. The cover portion includes a top wall, two sidewalls, and a middle wall. An airflow channel is bounded by the top wall and the sidewalls. The airflow channel includes an air inlet and a first air outlet. The middle wall is arranged between the first and second electronic components. A second air outlet is defined in one of the sidewalls between the middle wall and the air inlet. The guiding panel is installed between the sidewalls, and an end of the guiding panel resists against a top of the middle panel. The airflow channel is divided into a first airflow channel and a second airflow channel by the guiding panel and the middle wall, respectively receiving the first and second electronic components.

### BACKGROUND

1. Technical Field

The present disclosure relates to electronic devices, and more particularly to an electronic device with an air duct.

2. Description of Related Art

Electronic components, such as expansion cards, in electronic devices generate considerable heat during operation, which can damage other components in the electronic devices.

A commonly used heat dissipation device includes a plurality of fans mounted on the electronic device chassis. The fans guide air flowing in the electronic device chassis through the expansion card. However, some of the expansion cards may be mounted further away from the fans than other cards and are not efficiently cooled.

### BRIEF DESCRIPTION OF THE DRAWINGS

The components of the drawings are not necessarily drawn to scale, the emphasis instead being placed upon clearly illustrating the principles of the embodiments of the display device. Moreover, in the drawings, like reference numerals designate corresponding parts throughout several views.

FIG. 1 is an exploded, isometric view of an exemplary embodiment of an electronic device, the electronic device includes two air ducts.

FIG. 2 is an exploded, isometric view of one of the air ducts of FIG. 1, but viewed from another perspective.

FIG. 3 is an inverted view of FIG. 2.

FIG. 4 is an assembled, isometric view of the air duct of FIG. 2.

FIG. 5 is an isometric, partially cutaway view of FIG. 4.

FIG. 6 is an assembled, isometric view of FIG. 1.

FIG. 7 is a sectional view of FIG. 6, taken along the line of VII-VII.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

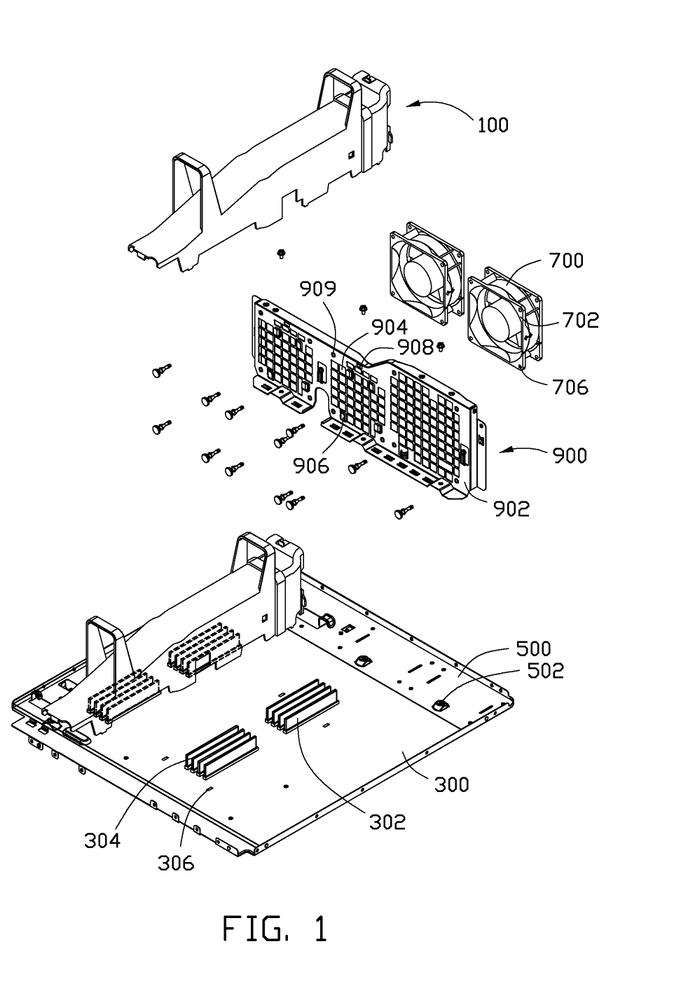

Referring to FIG. 1, an embodiment of an electronic device includes a base 500, a motherboard 300 fixed on the base 500, a support bracket 900, two air ducts 100, and two fans 700. In the embodiment, the electronic device is a server. A plurality of fixing holes 502 is defined in a side of the base 500.

The motherboard 300 includes a plurality of parallel first electronic components 302 installed on the motherboard 300, and a plurality of parallel second electronic components 304 installed on the mother board 300 respectively aligned with the first electronic components 302. Two mounting holes 306 are defined in the motherboard 300, at two opposite sides of either the first electronic components 302 or the second electronic components 304. In the embodiment, the first and second electronic components 302 and 304 are memory cards.

The support bracket 900 includes a substantially rectangular positioning plate 902 and a fixing plate 903 extending from a bottom of the positioning plate 902. Two vent areas 904 are defined in the positioning plate 902. Two hooks 906 extend from the positioning plate 902, at two opposite sides of a lower portion of each vent area 904, respectively. A latching hole 908 is defined in the positioning plate 902, above each vent area 904. Four fixing holes 909 are defined in the positioning plate 902, at four corners of each vent area 904, respectively. A plurality of installing holes (not labeled) is defined in the fixing plate 903.

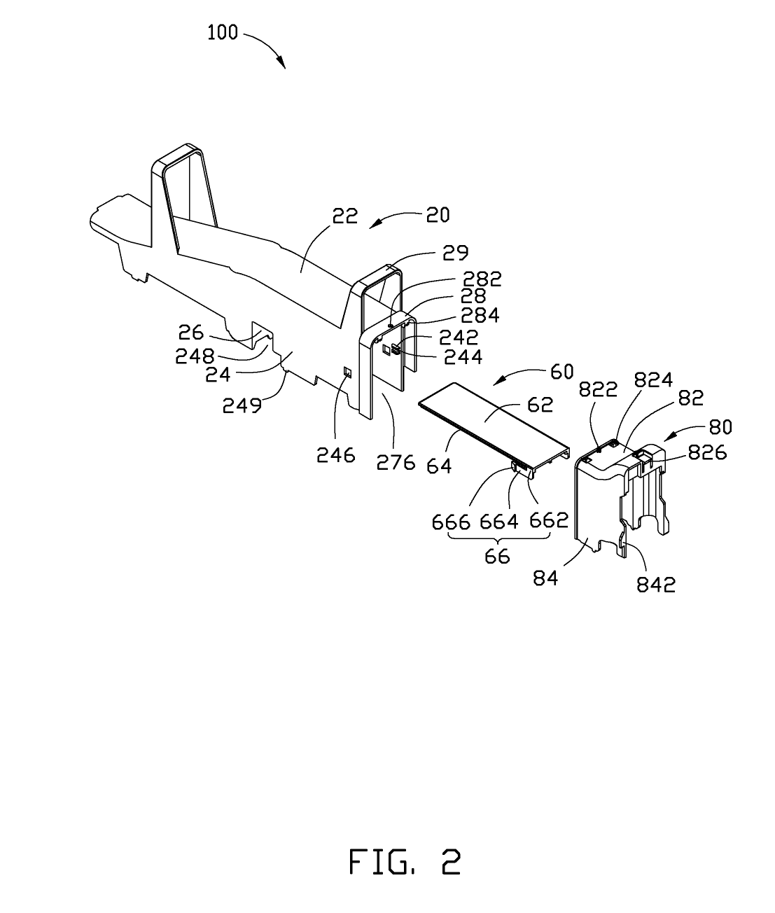

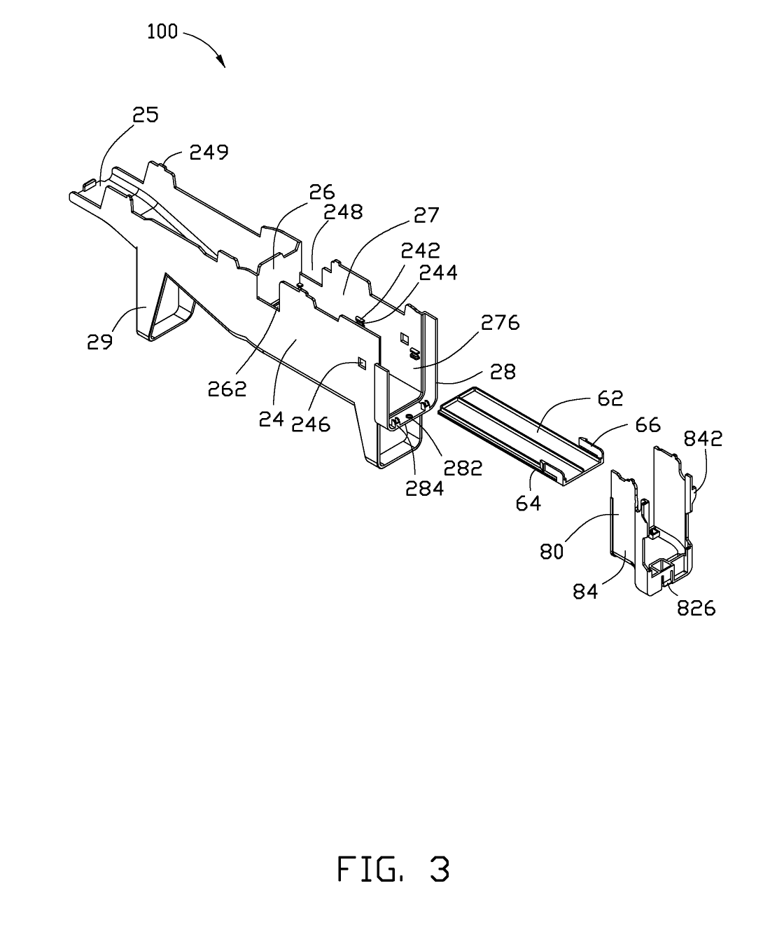

Referring to FIG. 2 and FIG. 3, each air duct 100 includes a cover portion 20, a rectangular guiding panel 60, and a substantially U-shaped connecting member 80.

The cover portion 20 is substantially U-shaped, and includes a top wall 22, two sidewalls 24 extending in a substantially perpendicular manner from two opposite sides of the top wall 22, and a middle wall 26 connected between middles of lower portions of the sidewalls 24 away from the top wall 22. The top wall 22 is slantingly recessed from a middle to a rear end of the cover portion 20. The top wall 22 and two sidewalls 24 cooperatively bound an airflow channel 27, with an air inlet 276 and a first air outlet 25 formed at a front end opposite to the rear end and the rear end of the cover portion 20. An opening 262 is defined between the top wall 22 and the middle wall 26. A plurality of support pieces 242 perpendicularly protrudes from an inner surface of each sidewall 24, between the middle wall 26 and the air inlet 276. The support pieces 242 of each sidewall 24 cooperatively form a slide slot 244. The slide slots 244 of the sidewalls 24 are opposite to each other, and parallel to the top wall 22. Two fixing holes 246 are respectively defined in the sidewalls 24, adjacent to the air inlet 276. Two second air outlets 248 are defined in bottoms of the sidewalls 24, respectively, between the air inlet 276 and the middle wall 26. Two positioning blocks 249 protrude from the bottom of each sidewall 24. A substantially U-shaped flange 28 extends from the top wall 22 and the sidewalls 24, at the front end of the cover portion 20. Two protrusions 284 protrude from an inner surface of a top of the flange 28. A fixing hole 282 is defined in the top of the flange 28, between the protrusions 284. Two operation portions 29 extend up from the top wall 22, respectively at the front and rear ends.

The guiding panel 60 includes a rectangular main body 62. Two sliding pieces 64 respectively extend from two opposite sides of the main body 62. Two opposite resilient latches 66 respectively protrude down from the sides of the main body 62, at a front end of the main body 62. Each latch 66 includes a connecting plate 662 extending down from the main body 62, a resilient extension plate 664 extending rearward from a distal end of the connecting plate 662, and a substantially wedge-shaped hook 666 extending out from a distal end of the extension plate 664.

The connecting member 80 includes a top plate 82 and two side plates 84 respectively extending down from two opposite sides of the top plate 82. Two engaging holes 824 are defined in a rear end of the top plate 82. A positioning pin 822 protrudes up from the rear end of the top plate 82, between the engaging holes 824. A latch 826 protrudes from a front end of the top plate 82. Two tabs 842 protrude out from front sides of the side plates 84, respectively.

Each fan 700 includes two parallel boards 702. Four fixing holes 706 are defined in four corners of each board 702, respectively.

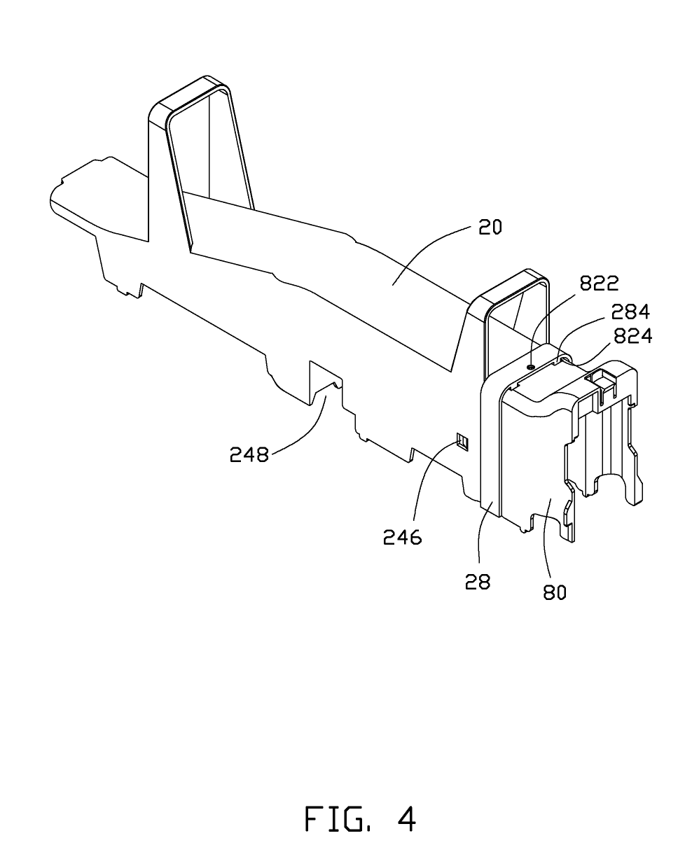

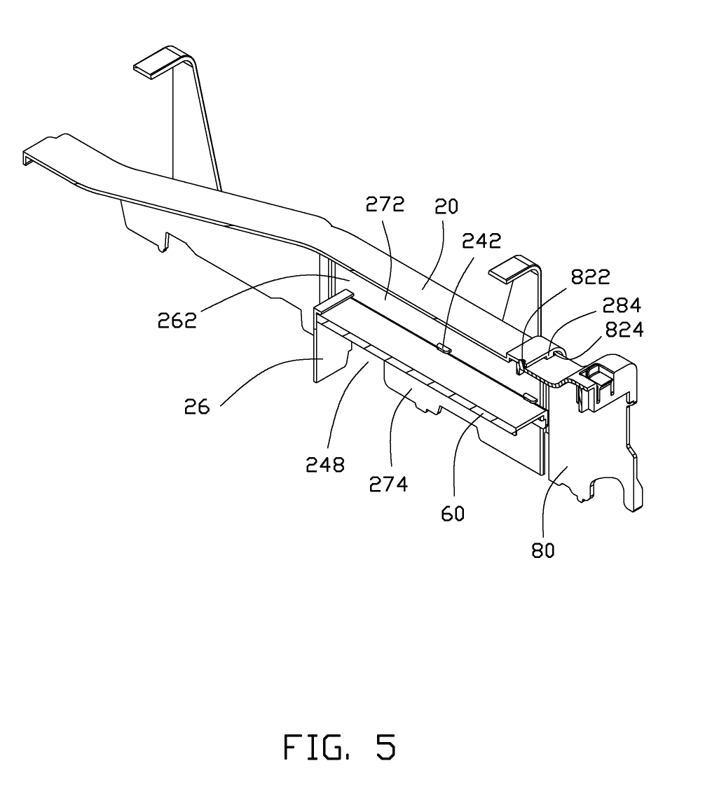

Referring to FIGS. 4-5, in assembly of each air duct 100, the sliding pieces 64 of the guiding panel 60 are slidably inserted into the corresponding slide slots 244. The guiding panel 60 is moved toward the middle wall 26, and hooks 666 respectively resist against the inner surfaces of the sidewalls 24, deforming the extension plates 664. Once the hooks 666 align with fixing holes 246, the extension plates 664 restore to make the hooks 666 engage in the corresponding fixing holes 246. The guiding panel 60 is latched between the sidewalls 24. The rear end of the guiding panel 60 resists against a top of the middle wall 26 adjacent to the opening 262. The top wall 22, the sidewalls 24, and the guiding panel 60 cooperatively bound a first airflow channel 272. The guiding panel 60, the sidewalls 24, and the middle wall 26 cooperatively bound a second airflow channel 274 communicating with the second air outlets 248. The rear end of the connecting member 80 is covered by the flange 28. The positioning pin 822 is engaged in the fixing hole 282. The protrusions 284 are latched in the engaging holes 824. Therefore, the connecting member 80 is fixed to the cover portion 20.

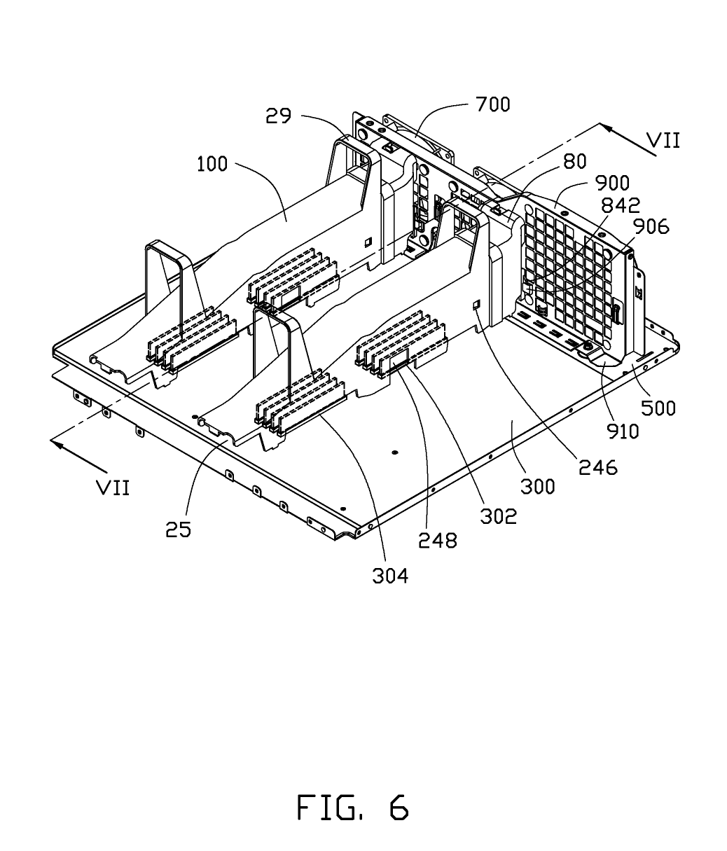

Referring to FIG. 6, in assembly of the electronic device, the support bracket 900 is supported on the base 500. Fasteners extend through the installing holes of the fixing plate 903, to screw into the corresponding fixing holes 502 of the base 500, thereby fixing the support bracket 900 on the end of the base 500. The fans 700 are installed on a side of the positioning plate 902 opposite to the motherboard 300. Fasteners extend through the fixing holes 706 of the fans 700, to screw into the corresponding fixing holes 909 of the support bracket 900. The air ducts 100 are supported on the motherboard 300. The positioning blocks 249 of each cover portion 20 are aligned with the corresponding mounting holes 306 of the motherboard 300. The tabs 842 of each connecting member 80 are aligned with the corresponding hooks 906 of the support bracket 900. The operation portions 29 are pressed down. The positioning blocks 249 are engaged in the corresponding mounting holes 306. The tabs 842 are engaged with the hooks 906. The latches 826 of the connecting members 80 are latched in the corresponding latching holes 908 of the support bracket 900. Therefore, the air ducts 100 are fixed on the motherboard 300. The first electronic components 302 are received in the second airflow channels 274, and the second electronic components 304 are received in the first airflow channels 272.

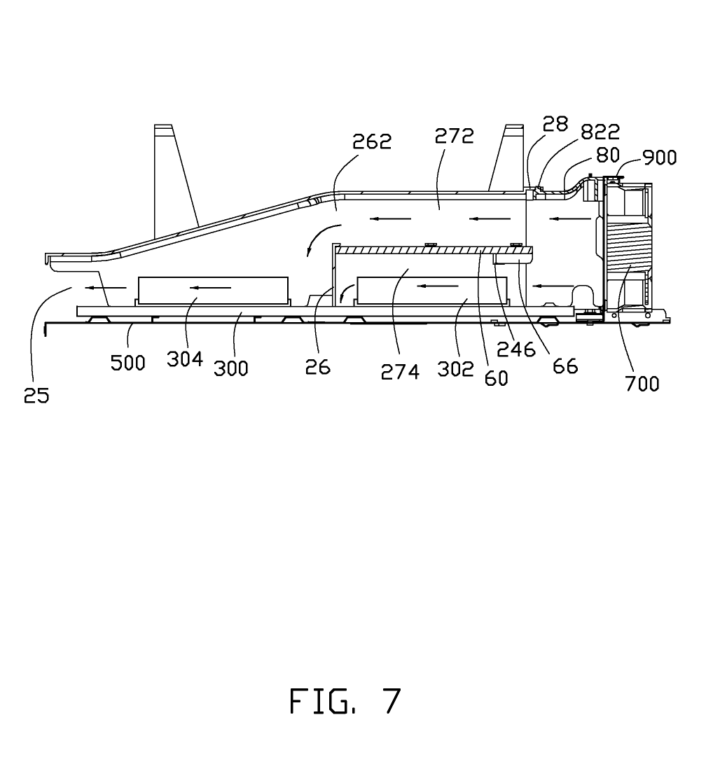

Referring to FIG. 7, in use, when the first and second electronic components 302 and 304 generate heat, the fans 700 operate and generate airflow. A part of the air flows through the first airflow channel 272 to cool the second electronic component 304. Heated air from the second electronic component 304 is exhausted through the first air outlets 25. Another part of the air flows through the second airflow channels 274 to cool the first electronic components 302. Heated air from the first electronic components 302 is exhausted through the second air outlets 248.

In another embodiment, the connecting member 80 is omitted, and the cover portion 20 is directly fixed to the support bracket 900.

It is to be understood, however, that even though numerous characteristics and advantages of the embodiment(s) have been set forth in the foregoing description, together with details of the structures and functions of the embodiment(s), the disclosure is illustrative only, and changes may be made in detail, especially in matters of shape, size, and arrangement of parts within the principles of the disclosure to the full extent indicated by the broad general meaning of the terms in which the appended claims are expressed.

1. An air duct comprising:
a cover portion comprising a top wall, two sidewalls extending down from two opposite sides of the top wall, and a middle wall connected between middles of lower portions of the sidewalls away from the top wall, the top wall and the sidewalls cooperatively bound an airflow channel, with an air inlet and a first air outlet respectively formed at a front end and a rear end of the cover portion, a second air outlet is defined in a bottom one of the sidewalls, between the air inlet and the middle wall; and
a guiding panel comprising a main body latched between the sidewalls of the cover portion, parallel to the top wall and adjacent to the air inlet, wherein an opening is defined between the top wall and a top of the guiding panel, a rear end of the guiding panel resists against the top of the middle wall;
wherein the top wall, the sidewalls, and the guiding panel cooperatively bound a first airflow channel, the guiding panel, the sidewalls, and the middle wall cooperatively bound a second airflow channel communicating with the second air outlet.

2. The air duct of claim 1, wherein a plurality of support pieces perpendicularly protrude from an inner surface of each sidewall, between the middle wall and the air inlet, the support pieces of each sidewall cooperatively bound the slide slot.

3. The air duct of claim 2, wherein two operation portions extend up from the top wall, respectively at the front and rear ends.

4. The air duct of claim 1, wherein two opposite slide slots are defined in the sidewalls, the slide slots are opposite to each other, and parallel to the top wall, two sliding pieces respectively extend from two opposite sides of the main body, the sliding pieces are slidably inserted into the corresponding slide slots.

5. The air duct of claim 4, wherein the top wall is slantingly recessed down from a middle to a rear end of the cover portion.

6. The air duct of claim 4, wherein two fixing holes are respectively defined in the sidewalls, adjacent to the air inlet, two opposite resilient latches respectively protrude down from the sides of the main body, at a front end of the main body, each latch comprises a connecting plate extending down from the main body, a resilient extension plate extending rearward from a distal end of the connecting plate, and a hook extending out from a distal end of the extension plate, the hooks are engaged in the corresponding fixing holes.

7. The air duct of claim 4, wherein the air duct further comprises a connecting member fixed to the air inlet of the cover portion, the connecting member comprises a top plate and two side plates respectively extending down from two opposite sides of the top plate, two engaging holes are defined in a rear end of the top plate, a flange extends from the top wall and the sidewalls, at the front end of the cover portion, two protrusions protrude from an inner surface of a top of the flange, the protrusions are latched in the engaging holes.

8. An electronic device comprising:
a base;
a fan mounted to the base;
a motherboard fixed on the base, wherein the motherboard comprises a plurality of first electronic components installed on the motherboard, adjacent to the fan, and a plurality of second electronic components installed on the motherboard in same rows with the first electronic components, away from the fan; and
an air duct fixed on the motherboard, wherein the air duct comprises a cover portion and a guiding panel, the cover portion comprising a top wall, two sidewalls extending down from two opposite sides of the top wall, and a middle wall connected between middles of lower portions of the sidewalls away from the top wall, the middle wall is installed between the first and second electronic components, the top wall and the sidewalls cooperatively bound an airflow channel receiving the first and second electronic components, respectively at a front end and a rear end of the cover portion, with an air inlet and a fist air outlet formed at the front end and the rear end of the cover portion, the air inlet aligns with the fan, a second air outlet is defined in a bottom of one of the sidewalls, between the air inlet and the middle wall, the guiding panel comprises a main body is latched between the sidewalls of the cover portion, parallel to the top wall and adjacent to the air inlet, an opening is defined between the top wall and a top of the middle wall, a rear end of the guiding panel resists against the top of the middle wall, wherein the top wall, the sidewalls, and the guiding panel cooperatively bound a first airflow channel receiving the first electronic components, the guiding panel, the sidewalls, and the middle wall cooperatively bound a second airflow channel communicating with the second air outlet and receiving the second electronic components.

9. The electronic device of claim 8, wherein two opposite slide slots are defined in the sidewalls, the slide slots are opposite to each other, and parallel to the top wall, two sliding pieces respectively extended from opposite side of the main body, the sliding pieces are slidably inserted into the corresponding slide slots.

10. The electronic device of claim 9, wherein a plurality of support pieces perpendicularly protrude from an inner surface of each sidewall, between the middle wall and the air inlet, the support pieces of each sidewall cooperatively bound the slide slot.

11. The electronic device of claim 8, wherein the top wall is slantingly recessed down from a middle to the rear end of the cover portion.

12. The electronic device of claim 11, wherein two operation portions extend up from the top wall, respectively at the front and rear ends.

13. The electronic device of claim 8, wherein two fixing holes are defined in the sidewalls, adjacent to the air inlet, two opposite resilient latches protrude down from the sides of the main body, at a front end of the guiding panel, each latch comprises a connecting plate extending down from the guiding panel, a resilient extension plate extending rearward from a distal end of the connecting plate, and a hook extending out from a distal end of the extension plate, the hooks are engage in the corresponding fixing holes.

14. The electronic device of claim 8, wherein the electronic device further comprises a support bracket fixed on the base at a side of the motherboard, a vent area is defined in the positioning plate, the fan is fixed to a side of the positioning plate opposite to the motherboard, the fan aligns with the vent area.

15. The electronic device of claim 14, wherein the air duct further comprises a connecting member fixed between the support bracket and the air inlet of the cover portion.

16. The electronic device of claim 15, wherein the connecting member comprises a top plate and two side plates respectively extending down from two opposite sides of the top plate, two engaging holes are defined in a rear end of the top plate, a flange extends from the top wall and the sidewalls, at the front end of the cover portion, two protrusions protrude from an inner surface of a top of the flange, an end of the connecting member is covered by the flange, the protrusions are latched in the engaging holes.

17. The electronic device of claim 15, wherein a latch protrudes from the other end of the top plate of the connecting member, a latching hole is defined in the support bracket, the latch is latched in the latching hole of the support bracket.
